(19) United States
(12) Patent Application Publication
(10) Pub. No.: US 2023/0228921 A1
(43) Pub. Date: Jul. 20, 2023

(54) Electronic Devices Having Displays With Inactive Area Structures

(71) Applicant: Apple Inc., Cupertino, CA (US)

(72) Inventors: Martin Melcher, Paris (FR); Christopher E Glazowski, Santa Cruz, CA (US); David L Wei, San Diego, CA (US); Michael B Wittenberg, San Francisco, CA (US); Sebastian Knitter, San Francisco, CA (US); Yu Wang, Santa Clara, CA (US)

(21) Appl. No.: 18/145,209

(22) Filed: Dec. 22, 2022

Related U.S. Application Data
(60) Provisional application No. 63/300,894, filed on Jan. 19, 2022.

(51) Int. Cl. G02B 5/08; G02B 5/28; H10K 59/65; H10K 50/84; H10K 50/86

(52) U.S. Cl. CPC G02B 5/08; G02B 5/285; H01L 27/3234; H01L 51/524; H01L 51/5281

(57) ABSTRACT

An electronic device may be provided with a display. The display may have a display cover layer. The display may have an active area with pixels and an inactive area adjacent to the active area. A reflective layer or a reflective portion of the cover layer may be formed in the inactive area and may have a reflectivity that matches a reflectivity of the active area of the display. The reflective portion may include texture or particles embedded in an ink layer. A PVD layer may be formed on the reflective layer and may have a color that matches a color of the active area. A polarizer layer may also extend across the active areas and inactive areas. In this way, an appearance of the inactive area may match an appearance of the active area when the display is off.

This application claims the benefit of provisional application No. 63/300,894, filed Jan. 19, 2022, which is incorporated by reference herein in its entirety.

### BACKGROUND

This relates generally to electronic devices, and, more particularly, to electronic devices with displays.

Electronic devices such as laptop computers, cellular telephones, and other equipment are sometimes provided with displays. In some devices, displays may have inactive areas under which circuitry and various components may be mounted.

It can be challenging to incorporate desired functionality into devices such as these. For example, it may be difficult to incorporate light-based devices such as light sensors and cameras into a device under an inactive region of a display without disturbing the appearance of the display.

### SUMMARY

An electronic device may be provided with a display. The display may have a display cover layer. The display cover layer may overlap display layers, such as a touch sensor, an inorganic or organic light-emitting diode display layer, a liquid crystal display layer, or display layers of other display platforms.

The display may have an active area with pixels and an inactive area. The inactive area may have structures that are optically matched to the pixels so that the inactive and active areas have similar visual appearances when the display is off. The inactive area structures may include textured layer(s), ink with embedded particles, portions of a polarizer layer, and/or a physical vapor deposition (PVD) layer. The inactive area structures may reflect light at a similar angle to light that reflects from the active area and may have a similar color to the active area.

An optical window may be formed in the inactive area. A light-based component such as an ambient light sensor, proximity sensor, or image sensor may be mounted in the electronic device in alignment with the optical window. The inactive area structures may have an opening with which the light-based component is aligned. The light-based component may receive light through the opening.

### BRIEF DESCRIPTION OF THE DRAWINGS

FIG. 1 is a schematic diagram of an illustrative electronic device in accordance with an embodiment.

FIG. 2 is a perspective view of an electronic device having optical windows for light-based components such as light sensors in accordance with an embodiment.

FIG. 3 is a top view of a portion of an illustrative electronic device having windows for light-based components in accordance with an embodiment.

FIG. 4 is a cross-sectional side view of a portion of an illustrative electronic device with a display and having a textured layer in an inactive region of the display in accordance with an embodiment.

FIG. 5 is a cross-sectional side view of a portion of an illustrative electronic device with a textured layer in accordance with an embodiment.

FIG. 6A is a top view of an illustrative array of pixels in accordance with an embodiment.

FIG. 6B is a top view of an illustrative textured layer in accordance with an embodiment.

FIG. 7 is a cross-sectional side view of a portion of an illustrative electronic device having a display with an active area and an inactive area and a textured region in the inactive area, and light reflecting from the active and inactive areas in accordance with an embodiment.

FIG. 8 is a cross-sectional side view of a portion of an illustrative electronic device with a display and having a layer of ink with embedded particles in an inactive region of the display in accordance with an embodiment.

FIG. 9 is a cross-sectional side view of a portion of an illustrative electronic device with a display and having a PVD layer that extends across active and inactive areas of the display in accordance with an embodiment.

FIG. 10A is a cross-sectional side view of a portion of an illustrative electronic device with a display and having a polarizer in active and inactive regions of the display in accordance with an embodiment.

FIG. 10B is a cross-sectional side view of a portion of an illustrative electronic device with a display and having a polarizer in active and inactive regions of the display, the polarizer having a bleached portion, in accordance with an embodiment.

FIG. 10C is a cross-sectional side view of a portion of an illustrative electronic device with a display and having a polarizer between two cover glass portions in active and inactive regions of the display in accordance with an embodiment.

### DETAILED DESCRIPTION

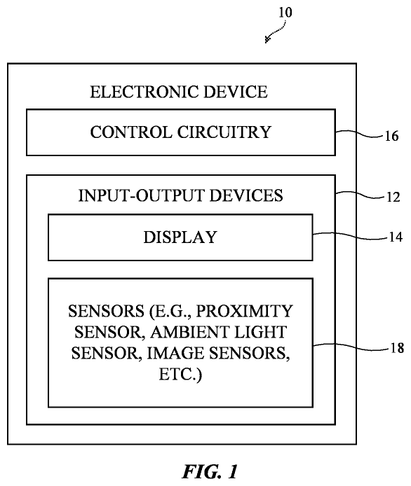

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

As shown in FIG. 1, electronic device 10 may have control circuitry 16. Control circuitry 16 may include storage and processing circuitry for supporting the operation of device 10. The storage and processing circuitry may include storage such as nonvolatile memory (e.g., flash memory or other electrically-programmable-read-only memory configured to form a solid state drive) and volatile memory (e.g., static or dynamic random-access-memory). Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, light-emitting diodes for components such as status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Input-output devices 12 may also include sensors 18. Sensors 18 may include a capacitive proximity sensor, a light-based proximity sensor, an ambient light sensor, a light-based fingerprint sensor, a fingerprint sensor based on a capacitive touch sensor, a magnetic sensor, an accelerometer, a force sensor, a touch sensor for a button or track pad, a temperature sensor, a pressure sensor, a compass, a microphone, a visible digital image sensor (visible-light camera), an infrared digital image sensor (infrared-light camera), and other sensors.

Sensors 18 may be used to gather user commands (e.g., commands that direct control circuitry 16 to take action), may be used to gather information on the environment surrounding device 10 (e.g., information on ambient light levels, ambient temperature, ambient atmospheric pressure, etc.), and may be used in performing biometric authentication operations (e.g., using a fingerprint sensor, using visible and/or infrared cameras, using voice recognition, etc.). After a user has been authenticated using biometric authentication operations and/or after entering a password or supplying other information to device 10, control circuitry 16 may provide the user with access to the features of device 10 (e.g., circuitry 16 may allow the user to make telephone calls, access stored information in storage in device 10, send text messages or email messages, etc.).

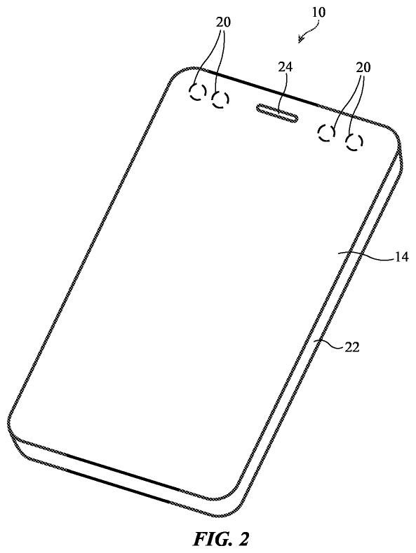

A perspective view of a portion of an illustrative electronic device is shown in FIG. 2. As shown in FIG. 2, electronic device 10 may be a portable electronic device such as a handheld device having opposing front and rear faces. In the example of FIG. 2, device 10 includes a display such as display 14 mounted in housing 22 on the front face of device 10. Configurations in which display 14 is mounted in other portions of an electronic device may be used, if desired (e.g., configurations in which display 14 is mounted to the upper housing in a laptop computer that has upper and lower housings coupled by a hinge, configurations in which display 14 is mounted to a housing in an all-in-one desktop computer, etc.). Housing 22, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 22 may be formed using a unibody configuration in which some or all of housing 22 is machined or molded as a single structure or may be formed using multiple structures (e.g., an internal frame structure, one or more structures that form exterior housing surfaces, etc.).

Display 14 may be protected using a display cover layer such as a layer of transparent glass, clear plastic, sapphire, or other clear layer. Openings may be formed in the display cover layer. For example, an optional opening may be formed in the display cover layer to accommodate speaker port 24 or other components. An optional opening may be formed in the cover layer to accommodate a button, or electronic device 10 may include a virtual button formed by a sensor operating through pixels in display 14. Openings may be formed in housing 22 to form communications ports (e.g., an audio jack port, a digital data port, etc.), to form openings for buttons, etc.

Display 14 may be a liquid crystal display, may be an electrophoretic display, may be an organic light-emitting diode display or other display with an array of light-emitting diodes, may be an organic light-emitting diode display with may be a plasma display, may be an electrowetting display, may be a display based on microelectromechanical systems (MEMs) pixels, may be a display having a pixel array formed from crystalline semiconductor light-emitting diode dies (sometimes referred to as microLEDs), or may be any other suitable display. Illustrative configurations in which display 14 is an organic light-emitting diode display may sometimes be described herein as an example.

Openings or other transparent regions in one or more of the layers of display 14 may be used in forming optical windows 20. There may be any suitable number of windows 20 in display 14 (e.g., at least one, at least two, at least three, at least four, two, four, fewer than ten, 3-7, etc. In the example of FIG. 2, there are four windows 20, each of which overlaps one or more associated light sensors (e.g., visible image sensors, infrared image sensors with optional infrared light-emitting diodes for providing illumination, color ambient light sensors, optical proximity sensors having infrared light-emitting diodes and corresponding infrared light detectors for detecting emitted infrared light that has reflected from an external object, and/or other light-based components in sensors 18). In general, there may be any suitable number of light-transmitting windows 20 in display 14 and these windows may be used in transmitting emitted and/or received visible light, infrared light, and/or other light.

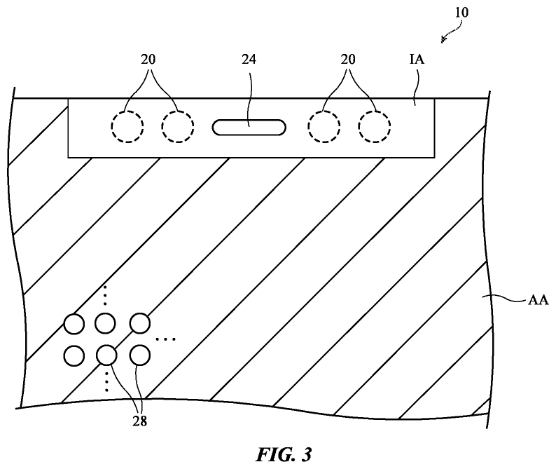

Display 14 may include an active area that contains an array of pixels for displaying images to a user. The overall footprint (shape when viewed from above) of display 14 may be rectangular or may have other suitable shapes. Display 14 may, for example, have a rectangular shape and the active area of display 14 may fill most of this rectangular shape. Inactive areas may be formed along one or more of the edges of the active area. As shown in FIG. 3, for example, inactive area IA may extend along part of the upper edge of display 14 and may overlap windows 20 and, if desired, may overlap speaker port 24. Active area AA may cover the remainder of the front face of device 10 and may include an array of pixels 28 for displaying images for a user. In some configurations, inactive areas may run along the left and right edges of display 14 and/or along the lower edge of display 14. In other configurations, display 14 is borderless along the right, left, and lower edges of display 14. If desired, display 14 may have one or more inactive areas IA that are completely surrounded by active area AA.

To provide display 14 with a uniform appearance, the display cover layer and polarizer for display 14 may extend over most or all of the front face of device 10. Openings for optional speaker port 24 and optional buttons may, if desired, be formed through the display cover layer and polarizer. Optical windows 20 may be formed under the display cover layer in inactive area IA. To enhance light transmission and avoid other optical effects due to the presence of the polarizer, each optical window 20 may include a transparent region that is in alignment with that window 20. The transparent region may be formed by creating an opening in one or more display layers, such as the polarizer layer, or by rendering polarizer material transparent by bleaching or other processing techniques.

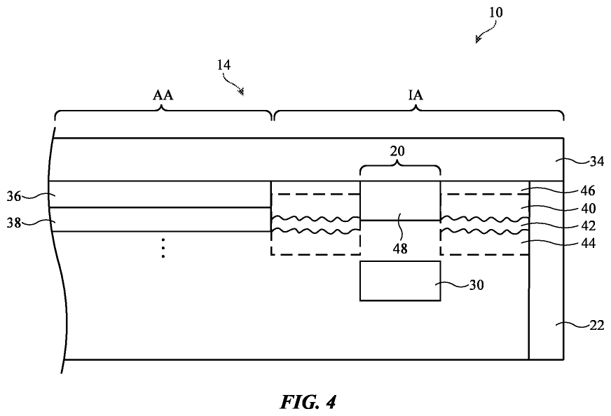

In some cases, it may be desirable for an appearance of inactive area IA to match an appearance of active area AA. Specifically, when the display is off (e.g., pixels 28 are not emitting light and displaying an image), it may be desirable for the front face of device 10 to have a uniform appearance in both inactive area IA and active area AA. To have the appearances of active area AA and inactive area IA match, it may be desirable for the colors of the areas to match, as well as an angle of light reflected by the two areas. An example of a display with inactive area structures to match an appearance of the inactive area to the active area is shown in FIG. 4.

As shown in FIG. 4, display 14 of device 10 may have an active area and an inactive area. Display cover layer 34 may cover both active area AA and inactive area IA. Display cover layer 34 may include plastic, glass, ceramic, or any other desired material.

Active area AA may include polarizer 36 and display layers 38. Display layers 38 may include different layers depending on the type of display used for display 14. For example, display layers 38 may include a color filter layer, a thin-film transistor layer, and a liquid crystal layer if display 14 is a liquid crystal display. Display layers 38 may include an anode layer, a cathode layer, and an emissive layer if display 14 is an organic light-emitting diode display. Display layers 38 may also include a touch sensitive layer, such as a capacitive touch sensitive layer. However, these examples are merely illustrative. Display layers 38 may include any desired layers, and display 14 may be any desired type of display.

To match an appearance of inactive area IA to active area AA when display 14 is off/not display images, textured layers may be used to match the reflection of light in the active and inactive areas. As shown in FIG. 4, textured layer 40 may be provided on display cover layer 34. Textured layer 40 may be a film, an embossed layer, or any other type of layer. In one example, textured layer 40 may be formed from resin that is embossed with the desired texture and then cured using ultraviolet (UV) light. In another example, a surface of cover layer 34 may be textured to form texture 40. However, this is merely illustrative. Any desired material may be used for textured layer 40.

Although textured layer 40 may reflect light in a manner that matches the reflection of active area AA, optional physical vapor deposition (PVD) layer 46 may be interposed between textured layer 40 and cover glass 34, if desired. PVD layer 46 may be a partial mirror that adds additional reflection to inactive area IA. For example, PVD layer 46 may have a reflection of at least 5%, at least 10%, less than 15%, between 5% and 10%, or any other desired reflection. If PVD layer 46 is included in inactive area IA, the combined reflectivity of textured layer 40 and PVD layer 46 may match the reflectivity of active area AA.

In addition to matching the reflection of light in the active and inactive areas, it may be desirable to match the colors of the two areas. Layer 42 may be a physical vapor deposition (PVD) layer that has a color that matches the color of active area AA when the display is off/not display images. For example, PVD layer 42 may be blue, black, or any other desired color. If desired, optional ink layer 44 may provide additional color to the inactive area.

PVD layer 42 may be formed thin-film interference filter. For example, PVD layer 42 may include alternating layers of high and low indexes of refraction, such as SiO₂ and Nb (and/or Nb₂O₅), respectively. The alternating layers with high and low indexes of refraction may be inorganic dielectric layers, as an example. Alternatively or additionally, Ti or Cr may be used for at least some of the high index layers. However, any desired materials may be used to form the high and low index layers within PVD layer 42.

PVD layer 42 may have L*, a*, and b* components in LAB color space. For example, PVD layer 42 may have an L* component of less than 30, less than 35, less than 50, at least 20, between 20 and 30, or any other desired value. PVD layer 42 may have an a* component of less than 0.35, less than 0.4, at least 0.2, or any other desired value. PVD layer 42 may have a b* component of at least −0.35, less than 0.0, less than −0.05, or any other desired value. In general, PVD layer 42 may have a color and reflectivity (in combination with textured layer 40), that matches the color and reflection of active area AA. In this way, an appearance of inactive area IA may match an appearance of active area AA.

Although textured layer 40, PVD layer 42, and optional layers 44 and 46 may help match the appearance of inactive area IA to active area AA, the layers may interfere with underlying components. For example, it may be desirable to include one or more components, such as component 30, in inactive area IA. Component 30 may be an optical component, such as an image sensor, an ambient light sensor, a color ambient light sensor, or other optical sensor; an infrared component; or any other desired component. To allow component 30 to receive and/or transmit light unimpeded by layers 40, 42, 44, and 46, window 20 may be formed in the layers. Filter coating 48 may fill the opening in window 20 to at least partially match an appearance of window 20 to the other portions of inactive area IA. For example, filter coating 48 may allow at least 5%, at least 10%, at least 20%, less than 50%, or any other desired amount of ambient light to pass to component 30, which may make measurements of the light based on the amount of filtered light detected. In this way, component 30 may make measurements on ambient light through window 20. However, one or more of textured layer 40, PVD layer 42, and optional layers 44 and 46 may extend across window 20, if desired.

Although textured layer 40 is shown on an interior surface of cover layer 34, this is merely illustrative. Textured layer 40 may be formed on an exterior surface and/or an interior surface of cover layer 34.

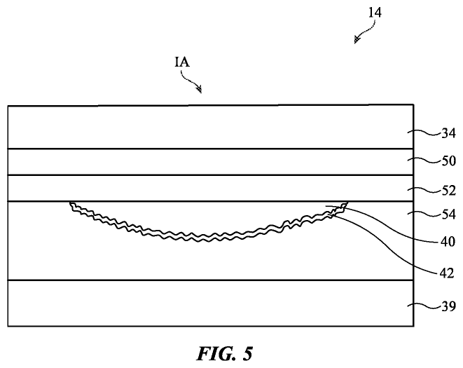

Although inactive area IA is shown at the edge of display 14 near housing 22, this is merely illustrative. Inactive area IA may be formed in any desired portion of display 14. For example, inactive area IA may be partially surrounded or entire surrounded by active area AA, or may be adjacent to active area AA. A detailed stack-up of the layers in inactive area IA is shown in FIG. 5.

As shown in FIG. 5, an adhesive layer 50, such as optically clear adhesive (OCA), may be applied to cover glass 34. Polymer layer 52 may be coupled to cover glass 34 by adhesive layer 50. Polymer layer 52 may be polyethylene terephthalate (PET), or may be any other desired polymer. Textured layer 40 may be formed on/attached to polymer layer 52, and PVD layer 42 may be formed on textured layer 40. Adhesive layer 54 may couple any display layers 39 (which may include some of display layers 38 of FIG. 4) to polymer layer 52 and PVD layer 42. In this way, textured layer 40 may be formed in inactive area IA of display 14.

The use of polymer layer 52 is merely illustrative, however. If desired, textured layer 40 may be applied directly to cover layer 34. Alternatively or additionally, textured layer 40 may be formed as an integral part of cover layer 34 (i.e., cover layer 34 may be formed with texture on a portion of the bottom surface, thereby forming textured portion 40). In general, any desired method may be used to form textured layer 40.

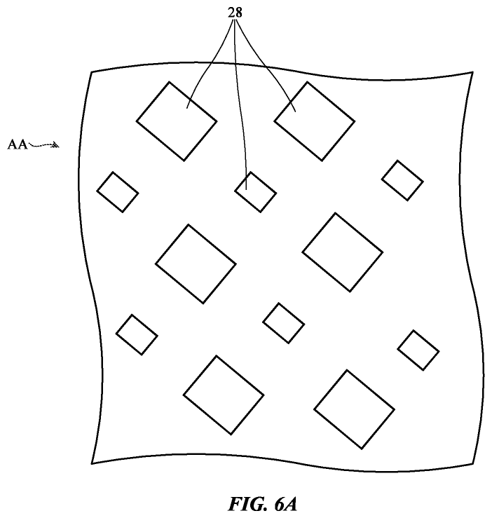

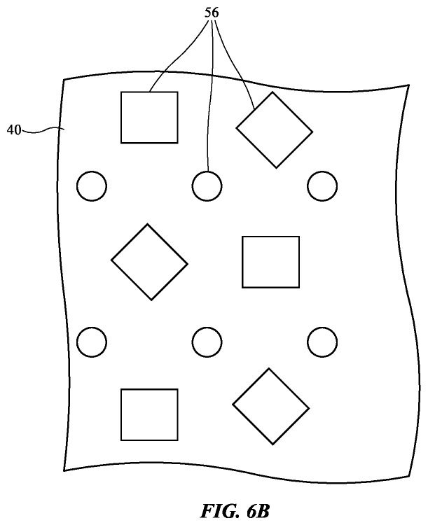

As previously discussed, textured layer 40 may be textured to have a reflectivity that matches the reflectivity of active area AA. For example, as shown in FIG. 6A, active area AA may include pixels 28 arranged in a particular pattern. Pixels 28 may include red, green, and blue pixels, and may be desired in any desired pattern. Pixels 28 may reflect light incident on display 14, particularly when pixels 28 are not actively outputting light to display an image. Therefore, as shown in FIG. 6B, to match the reflectivity of active area AA, textured layer 40 may have a texture 56 in a pattern that matches the pattern of pixels 28. For example, texture 56 may have a root mean square (RMS) roughness of at least 70 microns, at least 80 microns, at least 100 microns, less than 150 microns, between 70 and 100 microns, or any other desired amount to match the spacing between pixels 28. Light may be reflected from texture 56 on textured layer 40 in the same or similar manner to light reflected from pixels 28 in active area AA. In this way, reflected light from both active area AA and inactive area IA may look the same to a user of device 10.

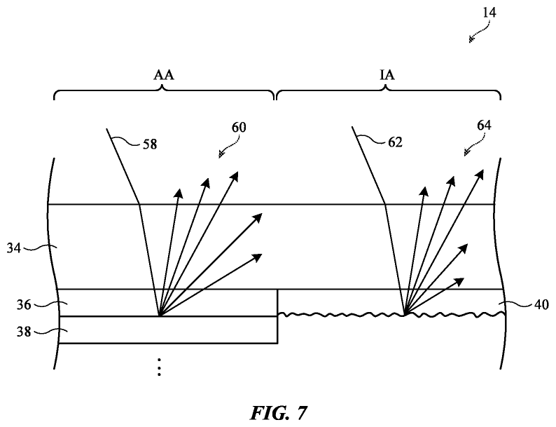

As an alternative to textured layer 40 have texture 56 to match the pattern of pixels 28, texture 56 may instead have a pseudo-random pattern. For example, the pseudo-random pattern may be created by imprinting curable resin with particles that are randomly distributed on a surface. The pseudo-random pattern may have texture with an RMS roughness of 1000 nm, at least 800 nm, less than 1200 nm, or any other desired RMS value. Although the pseudo-random pattern may not match the pattern of pixels 28 in active area AA exactly, the textured pattern may still reflect light similarly to the pixels and therefore have a similar appearance to that of active area AA to a user of device 10. Regardless of whether texture 56 or a pseudo-random pattern is used for textured layer 40, the resulting reflectivity is shown in FIG. 7.

As shown in FIG. 7, light 58 may be incident on display 14 in active area AA. Light 58 may refract through cover layer 34 and polarizer 64 and reflect off of display layers 38 as reflected light 60. Reflected light 60 may be scattered within a narrow angle (e.g., within 90°, within 80°, or other angle) with respect to an axis normal to display layers 68. Similarly, light 62 may refract through cover layer 34 and reflect off of textured layer 40 as reflected light 64. Reflected light 64 may be scattered within a narrow angle with respect to an axis normal to textured layer 40 to match the angle of reflected light 60. In this way, light may be reflected in active area AA and inactive area IA at the same angle, thereby having a similar appearance to a user of device 10.

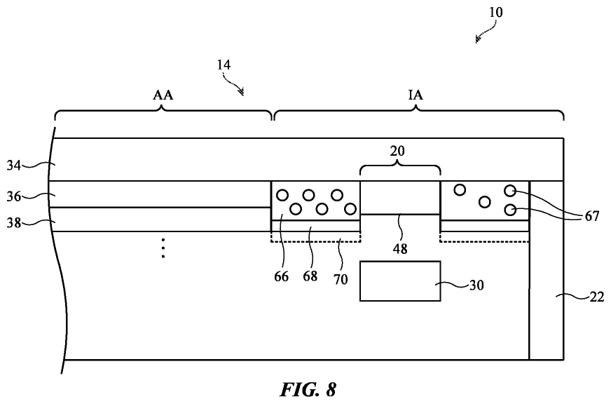

Although inactive area IA has been described as having textured layer 40 to reflect light in a similar manner to the display layers in active area AA, this is merely illustrative. In general, any desired layers may be used to match the reflectivity of the two area. An example using ink with reflective particles that may be used instead of or in addition to textured layer 40 is shown in FIG. 8.

As shown in FIG. 8, display 14 may include ink layer 66 with particles 67. Ink layer 66 may be an optically transparent ink or other desired ink. The optically transparent ink may be formed from a clear polymer with an index of refraction that matches an index of refraction of display cover layer 34, such as at least 1.5, less than 1.7, 1.52, or other desired index. Ink layer 66 may be at least 5 microns thick, less than 10 microns thick, or any other desired thickness.

Particles 67 may have a high index of refraction to reflect light incident on inactive area IA in a manner that matches the reflectivity of active area AA. For example, particles 67 may have an index of refraction of at least 1.7, at least 1.9, at least 2.5, less than 2.6, between 1.9 and 2.6, or any other desired index. Particles 67 may be formed from a metal oxide, such as TiO₂, ZrO₂, or other desired metal oxide. Particles 67 may have diameters of at least 0.2 microns, at least 0.5 microns, less than 2 microns, less than 2.5 microns, between 0.2 and 2 microns, or any other desired diameters. Particles 67 may reflect light incident on inactive area IA in a manner similar to textured layer 40 described in connection with FIGS. 4-7.

PVD layer 68 may be formed behind ink layer 66. In particular, PVD layer 68 may have a color that matches a color of active area AA when display layers 38 are off/not display images to a user of device 10. For example, PVD layer 68 may be black, blue, or any other desired color. If desired, PVD layer 68 may have the same composition and LAB color properties as PVD layer 42 described above in connection with FIG. 4. PVD layer 68 may be opaque, reflecting less than 1% of light, less than 2% of light, less than 5% of light, or other desired reflection. In this way, ink layer 66 with particles 67 may reflect light in a similar manner to active area AA, and PVD layer 68 may have a similar color to active area AA. Therefore, inactive area IA may have an appearance that matches an appearance of active area AA.

As an alternative to PVD layer 68 itself being a dark, opaque color, PVD layer 68 may instead be a partial mirror that reflects additional light to the light reflected by particles 67. For example, PVD layer 68 may be a partially reflective mirror that reflects at least 5% of light, at least 10% of light, less than 15% of light, or other desired amount of light. Therefore, additional light may be reflected in inactive area IA than when particles 67 are used alone for reflection.

If PVD layer 68 is a partially reflective mirror, it may be desirable to include optional ink layer 70 to impart a desired color on inactive area IA. For example, ink layer 70 may be black or blue ink and may match a color of active area AA.

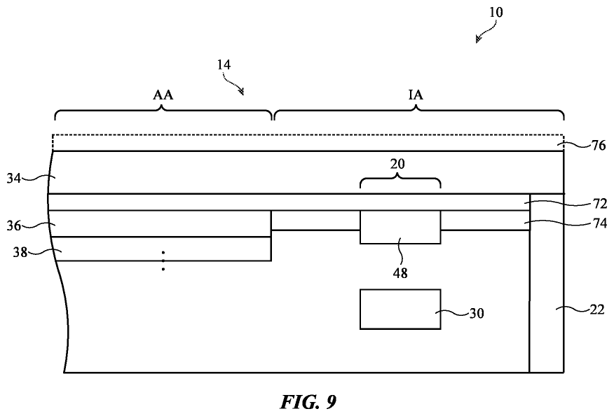

Another example of a display with a reflective surface that may be used instead of or in addition to textured layer 40 and/or ink layer 66 is shown in FIG. 9. As shown in FIG. 9, reflective layer 72 may extend across both active area AA and inactive area IA of display 14. In particular, reflective layer 72 may be on an interior surface of cover glass 34 and may reflect light incident on active area AA before it reaches display layers 38 and may also reflect light incident on inactive area IA. Reflective layer 72 may be a thin-film interference filter that includes alternating layers of high-index and low-index materials, may be a metal layer, such as titanium or chromium, or may be any other desired layer. Reflective layer 72 may have a reflectance of at least 5%, at least 7%, less than 10%, less than 15%, between 5% and 10%, or any other desired reflectance. Because reflective layer 72 may increase reflectance in a uniform manner across both the active and inactive areas of display 14, it may make the overall light reflected in both areas match to a greater extent than when reflective layer 72 is absent.

Ink or PVD layer 74 may be provided behind reflective layer 72. Layer 74 may be an ink or PVD layer with a color, such as blue or black, which matches a color of active area AA when display layers 38 are not emitting light/images to a user. In this way, reflective layer 72 may cause light to reflect at more similar angles in active area AA and inactive area IA, and ink/PVD layer 74 may impart a similar color on inactive area IA as a color of active area AA. As a result, the appearance of inactive area IA may match the appearance of active area AA.

Window 20 may be formed in ink/PVD layer 74 to allow light to pass to an underlying component, such as component 30, if desired. Reflective layer 72 may also have an opening aligned with the opening in ink/PVD layer 74 and window 20, if desired.

Although reflective layer 72 is shown on the interior surface of cover layer 34, this is merely illustrative. Reflective layer 72 may be on the exterior surface of cover layer 34 across active area AA and inactive area IA in optional position 76, if desired.

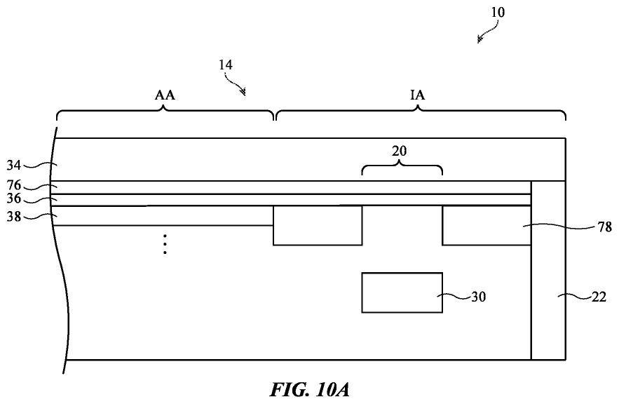

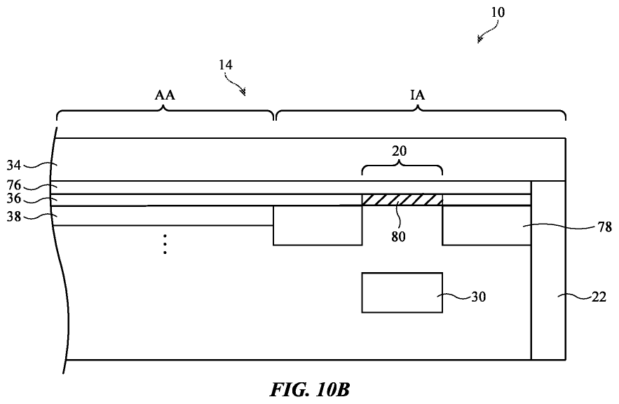

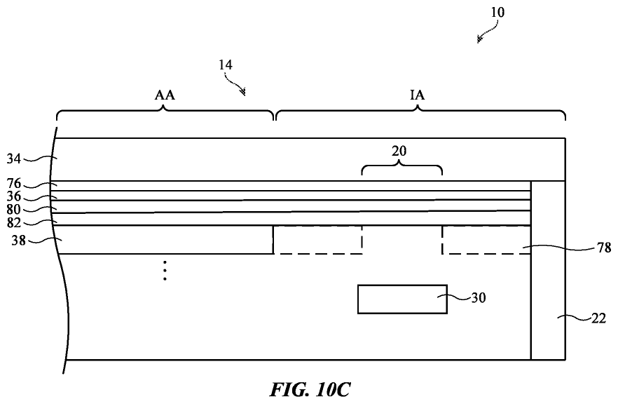

Alternatively or additionally, it may be desirable to match the active and inactive area appearances by extending the polarizer over both display areas. Examples of this arrangement are shown in FIGS. 10A-C.

As shown in FIG. 10A, polarizer 36, which may be attached to cover layer 34 by adhesive 76, may extend across active area AA and inactive area IA. Because polarizer 36 may impact the color of light reflected, extending polarizer 36 over inactive area IA may help match the appearance of inactive area IA to the appearance of active area AA.

Masking layer 78 may be provided on a bottom surface of polarizer 36 in inactive area IA. For example, masking layer 78 may be black and/or opaque to block underlying components within inactive area IA from view. The color of masking layer 78 may match a color of active area AA when display layers 38 are not emitting light/images.

To match the angle of light reflected from inactive area IA to light reflected from active area AA, a textured layer, such as textured layer 40, an ink layer, such as ink layer 66, or a reflective layer, such as reflective layer 72 may be used, as described above in connection with FIGS. 1-7, FIG. 8, and FIG. 9, respectively.

As shown in FIG. 10A, masking layer 78 may have an opening that is aligned with window 20 so that component 30 may receive light through window 20. In some cases, it may be desirable to modify polarizer 36 in window 20 to allow light to pass unimpeded. An example of modifying polarizer 36 within window 20 is shown in FIG. 10B.

As shown in FIG. 10B, polarizer 36 may have bleached region 80 that is aligned with the opening in masking layer 78 and window 20. In this way, component 30 may receive light through window 20, bleached region 80, and the opening in masking layer 78.

Another arrangement in which polarizer 36 may be extended over the active and inactive areas is shown in FIG. 10C.

As shown in FIG. 10C, polarizer 36 may extend across first cover layer 34 and be attached to first cover layer 34 by adhesive 76. Adhesive layer 80 may attach a bottom surface of polarizer 36 to second cover layer 82. Masking layer 78 may optionally be provided on second cover layer 82 to hide underlying components from a user of device 10. Masking layer 78 may have an opening to form window 20 and allow light to pass through window 20 unimpeded to component 30. Although not shown, polarizer 36 may have a bleached region aligned with window 20, if desired. Having first cover layer 34 and second cover layer 82 on either side of polarizer 36 may ensure that polarizer 36 is flat across active area AA and inactive area IA and therefore have the same appearance across display 14.

Although not shown in FIGS. 10A-10C, to match the angle of light reflected from inactive area IA to light reflected from active area AA, a textured layer, such as textured layer 40, an ink layer, such as ink layer 66, or a reflective layer, such as reflective layer 72 may be used, as described above in connection with FIGS. 1-7, FIG. 8, and FIG. 9, respectively.

The foregoing is merely illustrative and various modifications can be made to the described embodiments. The foregoing embodiments may be implemented individually or in any combination.

What is claimed is:

1. An electronic device having an interior and an exterior, the electronic device comprising:
a housing;
a display in the housing, wherein the display has an active area and an inactive area;
a cover layer that overlaps the display;
a reflective portion on the cover layer; and
a thin-film interference layer coupled to the reflective portion.

2. The electronic device defined in claim 1 wherein the reflective portion comprises a textured portion in the inactive area of the display.

3. The electronic device defined in claim 2 wherein the textured portion has a first reflectivity and wherein the active area of the display has a second reflectivity that matches the first reflectivity.

4. The electronic device defined in claim 3 wherein the display comprises an array of pixels arranged in a first pattern and wherein the textured portion comprises texture in a second pattern that matches the first pattern.

5. The electronic device defined in claim 3 wherein the textured portion comprises texture that is distributed pseudo-randomly across a surface of the textured portion.

6. The electronic device defined in claim 3 wherein the thin-film interference layer comprises a plurality of inorganic dielectric layers.

7. The electronic device defined in claim 6 further comprising:
a layer of ink on the thin-film interference layer.

8. The electronic device defined in claim 3 wherein the textured portion comprises a textured layer coupled to the cover layer.

9. The electronic device defined in claim 3 wherein the textured portion comprises a textured surface of the cover layer.

10. The electronic device defined in claim 1 wherein the reflective portion comprises a layer of ink with embedded particles in the inactive area of the display.

11. The electronic device defined in claim 10 wherein the layer of ink comprises a transparent material and the embedded particles comprise a material selected from the group consisting of: ZrO₂ and TiO₂.

12. The electronic device defined in claim 10 wherein the embedded particles have an index of refraction between 1.9 and 2.6.

13. The electronic device defined in claim 1 wherein the reflective portion comprises a reflective layer that extends across the active and inactive areas of the display.

14. The electronic device defined in claim 13 wherein the reflective layer has a reflectivity between 5% and 10%.

15. The electronic device defined in claim 1 wherein the textured portion has an opening, the electronic device further comprising:
a polarizer layer that extends across the active and inactive portions of the display, wherein the polarizer layer has a window; and
an optical component that receives light through the opening and the window.

16. The electronic device defined in claim 15 further comprising:
a glass layer interposed between the polarizer and the optical component.

17. An electronic device comprising:
a display having an active area and an inactive area;
a cover layer that overlaps the active and inactive areas of the display;
a reflective layer coupled to the cover layer; and
a PVD layer on the reflective layer.

18. The electronic device defined in claim 17 wherein the reflective layer overlaps the inactive area of the display and is selected from the group of layers consisting of: a thin-film interference layer and an ink layer with embedded particles.

19. The electronic device defined in claim 18 wherein the PVD layer has L*, a*, and b* components in LAB color space, the L* component is between 20 and 30, the a* component is less than 0.35, and the b* component is at least −0.35.

20. An electronic device comprising:
a display having an array of pixels that display an image in an active area and having an inactive area adjacent to the active area;
a cover layer that overlaps the active and inactive areas of the display;
a reflective portion in the inactive area, wherein the reflective portion has a first opening;
a PVD layer on the reflective portion, wherein the PVD layer has a second opening that is aligned with the first opening; and
a component that receives light through the first and second openings.
